(19) United States
(12) Patent Application Publication
(10) Pub. No.: US 2025/0274143 A1
(43) Pub. Date: Aug. 28, 2025

(54) METHOD AND APPARATUS FOR COMPUTING SYNDROMES, ERASURES AND ERRORS MAGNITUDES IN REED-SOLOMON ERROR CORRECTION

(71) Applicant: Vladimir Zentsov, Gatineau (CA)

(72) Inventor: Vladimir Zentsov, Gatineau (CA)

(21) Appl. No.: 18/588,926

(22) Filed: Feb. 27, 2024

(51) Int. Cl. H03M 13/15; H03M 13/11

(52) U.S. Cl. CPC H03M 13/1515; H03M 13/1177; H03M 13/1575

(57) ABSTRACT

The method and device for faster Reed-Solomon error decoding used a new approach—instead of calculating syndromes in a received signal in the traditional way to determine initially the coefficients of syndromes expansion into series of basic K linear-independent polynomials (called the basic group) of the certain powers belonging to the pre-determined set of powers. After that the syndromes which are necessary for accomplishing the stage 2—determination of the error positions—are calculated with the obtained coefficients, and the erasures and errors magnitudes on the step 3 are calculated through vector-matrix multiplication of a vector of the mentioned coefficients by the inverse of the conversion matrix (from the mentioned polynomials of the given and found on the stage 2 powers into the polynomials of the pre-determined set of powers).

Use of lesser number of necessary computations is achieved by using the remarkable properties of the conversion matrices obtained by the proper division of all n available powers into (n+1)/K certain groups with K powers in each. The K−1 obtained conversion matrices belong to the so called Latin Squares with their entries belonging to the limited alphabet of only K symbols. Due to that the efficient procedures for doing vector-matrix multiplications necessary for the mentioned operation of finding syndromes as well as inverting the conversion matrix have been developed. As a result the number of arithmetic operations for syndromes calculation and matrix inversion in comparison to the most advanced methods can be greatly reduced. In addition the approach allows for greater concurrency and using parallel processors while the known solutions are operated on scalars that contributes to further encoding speed up. The task has been completely solved for the case when n+1=K²=2^{2q}, q—an integer, among them it covers the cases of R-S code (255,239), (1023,991), (15,11), (63,55). There for the step 1 the number of necessary multiplications can be reduced in K/2 times, while the additions number remains the same. As for the step 3 for K=4 the method overpasses the known one almost 2 times in the number of the multiplications, for K=8 in 7/6 times and for K=16 more-less the same, with further K increase it is going to lose to the known methods.

### CROSS-REFERENCE TO RELATED APPLICATIONS

Patent USA Pending. METHOD AND APPARATUS FOR COMPUTING SYNDROMES, ERASURES AND ERRORS MAGNITUDES IN REED-SOLOMON ERROR CORRECTION, U.S. patent application 63/450,060, Mar. 5, 2023

### FIELD OF CLASSIFICATION SEARCH

### Field of Search: 714/784 714/785 714/781

H03M 13/00

### TECHNICAL FIELD

The invention relates to signal processing and particularly to a method and system for effective implementation of Reed-Solomon decoding, particularly calculation of syndrome magnitudes and errors with known position and erasure magnitudes.

### BACKGROUND OF INVENTION

### Description of the Related Art

The idea concerns a decoding algorithm of the Reed-Solomon code (n, n−2t). Reed-Solomon algorithm are widely used to carry out error correction in telecommunication and data storage mostly because of its ability to provide detection of multiple errors in bursts and erasures with known error positions. In spite of its relatively simple and fast implementation increased speed of data transmission requires increase speed for error correction. The algorithms involve complicated matrix operations which must be implemented in real time in most cases. So there is always need to provide faster and improved Reed-Solomon decoding.

Let V and U correspondingly the numbers of errors and erasures in the received signal. The common method of syndromes determination (step 1 in Reed-Solomon algorithm) [2.3] (see NPL.docx) is calculating the (2v+u) values of the received message polynomial of power n at the basic points Xᵢ using Horner' scheme. It requires n (2v+u) arithmetical operations in GF. In matrix form the syndromes vector F={Sᵢ} can be found as

$$F = P * R ,$$

with the vector of known magnitudes R={r(j)} of the RR received polynomial message

$$RR ( j ) = {\sum }_{i = 0}^{n - 2} r ( j ) {x}_{i}^{j} , \\ \begin{matrix}2 v + u - 1 & n - 1\end{matrix}$$

P={pᵢⱼ=a^{ij}}_{i=0 j=0}—the Vandermonde matrix, a—the Galois field (GF) primitive.

There are two commonly used methods and hardware for determination of magnitudes of erasures and errors (stage 3) after finding their position on the previous stage of R-S algorithm. The first (Forney' method) uses the unified approach with the stage 2 (determination of error position) with inherited from the algorithm founders wide use of scalar operations of polynomial multiplications and divisions in GF. Use of those operations without possibility of their concurrent implementation in GF leads to their slow implementation.

The alternative to the Forney' algorithm—vector-matrix multiplication of the syndromes vector by the inverse of the Vandermonde matrix constructed with the calculated syndromes [2]. The erasure gⱼₗ and errors Tᵢₗ values may be obtained simply by solving the following set of linear equations (LES).

$${S}_{i} = EE ( {a}^{i} ) = {\sum }_{l = 1}^{v} {g}_{jl} * {a}_{l}^{ij} + {\sum }_{l = 1}^{u} {f}_{jl} * {a}_{l}^{ij}$$

where

$$EE ( i ) = {\sum }_{j = 0}^{n - 2} e ( j ) {x}_{i}^{j}$$

the error signal to be found, the values e(j) are the re-numerated gⱼₗ and fⱼₗ. with their indexes belonging to J—the given set of errors and erasures positions (indexes polynomial powers),
Xᵢ=aⁱ—the basic points, where a is usually chosen to be 2.

In matrix form F=P**E,

$$2 v + u - 1$$

where E={eᵢ}ᵢ₌₀—the sought magnitudes,

$$2 v + u - 1 \qquad 2 v + u - 1$$

P*—a Vandermonde matrix of values of the polynomial of powers belonging to J at the basic points xᵢ=2ⁱ. J={jₗ}—the known positions of those errors, erasures and the dummy indexes.

To implement the task [U.S. Pat. No. 6,915,478. Method and apparatus for computing Reed-Solomon error magnitude] it is necessary to solve linear equation set, using matrix triangulation algorithm to find an inverse of the Vandermonde matrix. In [4] there is a description of the fast algorithm of finding P* inverse using L-U triangulation of the Vandermonde matrix P. Finding the inverse can be done using some other algorithms [U.S. Pat. No. 7,418,649 B2 Efficient implementation of Reed-Solomon erasure resilient codes in high-rate applications]. Its authors decided to use the specific generator matrices Vandermonde and Cauchy ones) for matrix inversion in order to introduce the necessary parallelism.

### SUMMARY

In the previous art syndromes magnitudes calculation constitutes the major chunk of computations for the whole algorithm using consecutive Horner' scheme and pipelined polynomial multiplications. The Horner scheme is difficult to implement efficiently [5] because of the difficulty to introduce some concurrency and parallelism in its hardware implementation. That scheme is a consecutive procedure in its nature and require consecutive operations of multiplication and addition following each other, it can be done just in n consecutive steps with just one addition and one multiplication on each step. Opposite for example the operation of vector-matrix multiplication of size n requires the same number of arithmetical operations, but it could be easily parallelized and accomplished in one step, with the a device consisting n multipliers and an adder for n terms adding.

In order to implement step 3 of R-S algorithm—calculation of errors and erasures magnitudes based on the Syndromes calculated—using Forney' algorithm it is necessary [2,3] to implement (v+u)*(3v+2u) arithmetical operations of m-bit-multiplications and additions in Galois Field GF (2^{m}). The fast algorithm of finding P* inverse using L-U triangularization of the Vandermonde matrix P requires 5/2*(v+u)*(v+u) operations.

As we see all the methods require too many operations especially for small coding schemes. My task was to speed-up the syndromes calculations and following the second method on stage 3 try to speed it up too.

### BRIEF DESCRIPTIONS OF DRAWINGS

FIG. 1 depicts the structure of hardware for calculating syndrome magnitudes and erasures and errors with known positions magnitudes based on syndromes expansion into series of basic K linear-independent polynomials of the powers of the certain-predetermined set (the basic group).

FIG. 2 illustrates the feasible embodiment of the recurrent structure for calculating the U matrices inverse obtained from the conversion matrix T.

FIG. 3 shows the structure of the block for the fast calculating the basic group coefficients for the case RS(n=2^{2q}−1, n−K), K=2^{2q}.

FIG. 4 depicts the flow-chart of the developed method of calculating the mentioned above magnitudes based on conversion of the basic group coefficients of syndromes expansion for the case RS(n=2^{2q}−1, n−K), K=2^{2q}.

FIG. 5 depicts the flow-chart of the developed algorithm of the U matrix inverse based on recursive determination of the matrix inverses of lesser sizes.

FIG. 6 shows the flow-chart of the developed method for the basic group coefficients calculation for the case RS(n=2^{2q}−1, n−K), K=2^{2q}.

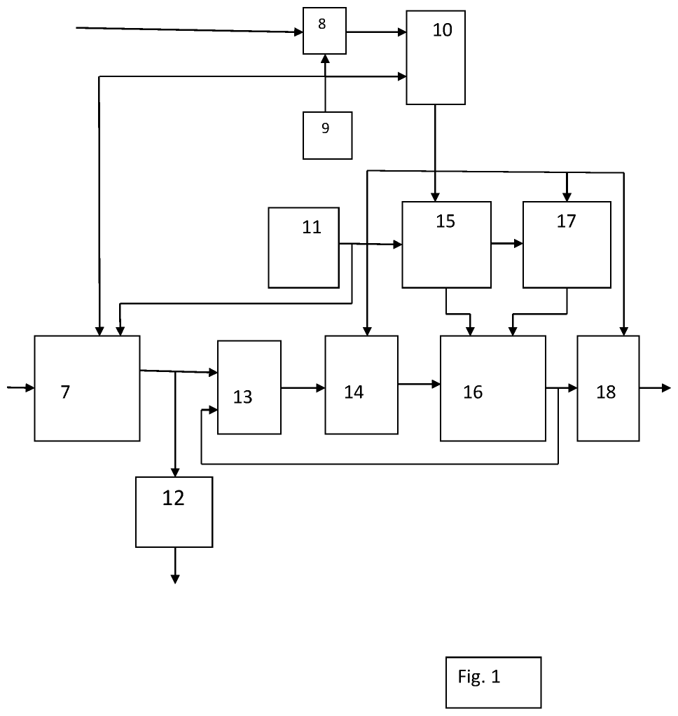

Some mathematical material including the matrices W, VV, A, TT used for the methods and devices described are in Appendix.

### REFERENCE NUMBERS

7—a vector-matrix multiplier (VMM) for obtaining syndromes expansion in the polynomials of the basic group.
8—a logical scheme for determining for every power in J its group number and its position number in the group's row of the matrix W.
9—a memory for storing the matrix W.
10—a logical scheme for re-ordering indexes from J to produce index array IR.
11—a memory for storing the matrix VV.
12—a VMM for calculating syndrome magnitudes.
13—a buffer memory for the coefficients of the basic group and the consecutive ones while doing (6)
14—a logical scheme for re-ordering those coefficients.
15—a logical scheme for forming T matrix.
16—a main VMM for implementing (6).
17—a U₁, U₂, U₃ matrices builder.
18—a logical scheme for the final re-ordering of coefficients.
19—U₁, U₂, U₃ matrices builder for the matrices of sizes K/2, K/4 . . . 4.
20—a builder of the matrix quadrants.
21—a matrix-by-matrix multiplier.
22—a register to store a RS codeword consisting of n symbols.
23—a complex decoder circuit with n inputs and K outputs.
24—a logical scheme to control the decoder 23.
25—a set of K accumulated adders.
26—a set of K multipliers for multiplication by a constant.
27—an adder with K+1 inputs.

### DETAILED DESCRIPTION OF INVENTION

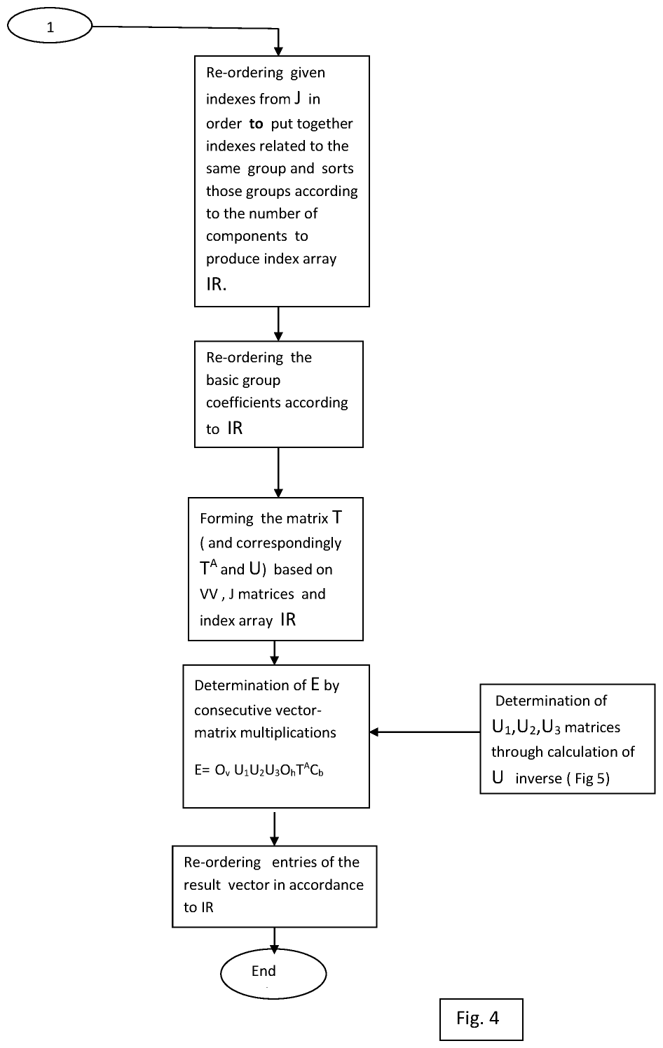

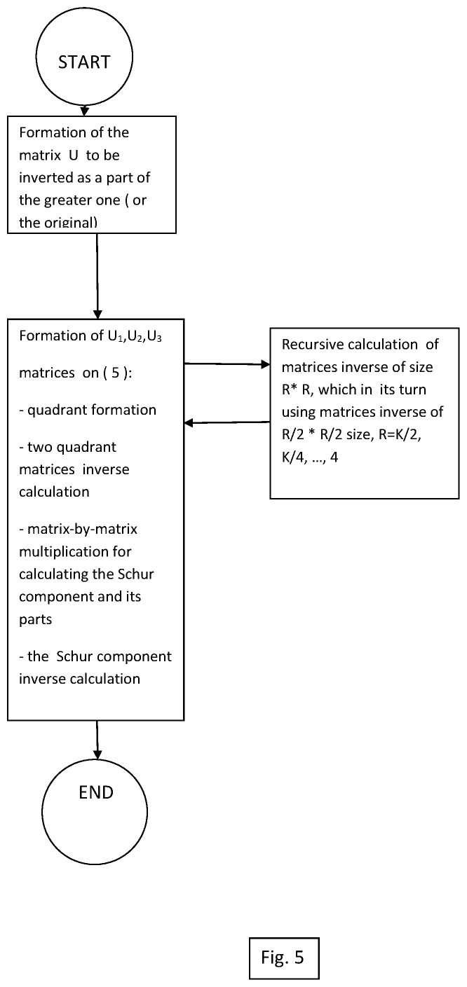

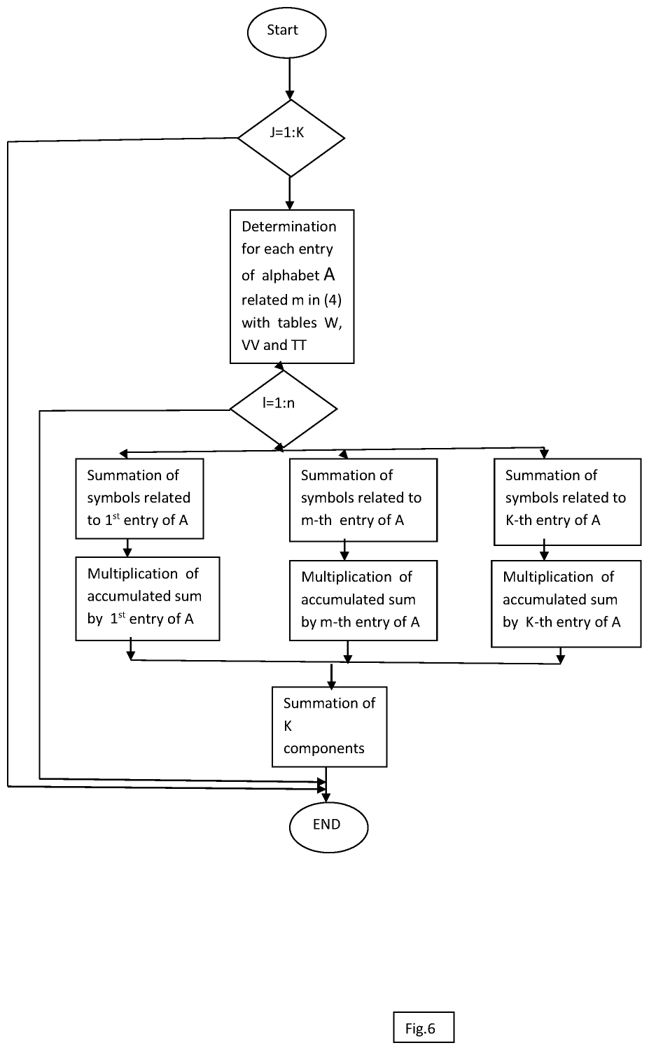

The flow-charts on FIG. 4-6 describe generally the developed method of finding syndromes magnitudes and error and erasure magnitudes, based on preliminary expansion of syndromes into series of the polynomials with their powers belonging to the certain set-so called basic indexes group. The method is based on the different approach to the decoding and treats it as an approximation task of interpolating V+U syndromes of magnitudes Sᵢ.

Let assume there are no greater than K=2^{2q} errors and erasures, J—the positions of the determined errors and the erasures in the received signal R (i) are known. Their number should be an even integer power of 2, if not so, 2^{2q}−u−V dummy errors (powers) should be added to the real positions of errors and erasures, where q—the minimal integer whose power of 2 is greater or equal U+V. In this case we bear in mind the values of those erasures at the fictions positions should be resulted in zeros. In RS(n, n−2t) define K=2t for simplicity and suppose K*K=n+1. So, It is necessary to determine the values of syndromes and errors in the received signal RR (i) with the known positions of those errors, erasures and the dummy indexes J={jₗ} of length K. In order to simplify the expressions let remunerate the double indexes iₗ, jₗ and the dummy indexes using I in J: I=0,1,2, . . . K−1, n+1-block length of R-S algorithm, for 1 greater than usual. The following (n+1)-th dummy polynomial of power n should be added to the existing ones in P:

$$K - 1 \\ P \{ i , n + 1 \} = {[ \begin{matrix}1 & 0 & 0 & 0 & … & 0\end{matrix} ]}^{′} . \\ i = 0$$

Given any K polynomials of different powers (indexes) it is possible to interpolate K magnitudes of the syndromes Sᵢ, among others with the indexes (powers) from the given sequence j€J:

$$F = ( P \text{*)} * E$$

where matrix P*—the part of P for j€J, i=0, . . . K−1 and E—the sought error (in the received signal) magnitudes.

Lets divide all n available indexes into (n+1)/K groups ((n+1)-th power to be artificially added) with K indexes in each group. Then coefficients of interpolation of Sᵢ in the series of the polynomials P_{I} of any I-th group can be found as F=P_{I}*C_{I}.

Lets choose arbitrary one group from them and call it the basic group, P_{B}—the part of P for indexes belonging to the basic group.

In order to find E

$$E = {P}_{*}^{- 1} * F$$

we can do it in two stages. On the first stage-determination of the coefficients of syndrome expansion in the series of the polynomials of the basic group:

$${C}_{b} = {P}_{B}^{- 1} * F \qquad ( 1 )$$

On the second stage—their transformation into the necessary E as

$${E = ( {P}_{B}^{- 1} * P \text{*)}}^{- 1} * {C}_{b}$$

The K-by-K matrix T=P_{B}⁻¹*P* consists of various columns of the corresponding conversion matrices—T_{I}=P_{B}⁻¹*P_{I} from groups I=1, 2, . . . K−1 into the basic group (I=0 is reserved for the basic group).

We have managed to find the “magical” division of all n+1 indexes into K groups, which produced the conversion matrices with the remarkable properties. This division can be described with the help of K by K matrix W, where each row of the matrix represents the sequence of indexes related to the particular group. Not only content of any row, but its ordering is crucially important. The matrices W for n=15,255,1023 (K=4, 16 and 32) are depicted in Appendix.

1. The T_{I} are orthonormal matrices, their inverses are the matrices themselves, and they are so called the Latin Squares LS (or derived from them through reordering rows or columns). As known LS is a K*K square matrix, consisting only of K entries from the limited alphabet A={a₁, a₂, . . . , aₖ} and each column and row contains just one and only one particular entry without omissions.

2. Inside the whole T there is no overlapping between two different columns as long as they are related to the same group and consequently in the same LS T_{I} (overlapping means there is no the same entry on the same row but at the different columns). But between two columns of the different groups (and two different LS matrices) there is ONE and ONY one overlapping 3. The scalar product of two columns of the same or another LS T_{I} are either 0 or 1 or the overlapping value.

The syndromes Sᵢ can be calculated with the obtained C_{b}

$$F = {P}_{B} * {C}_{b} \qquad ( 2 )$$

The coefficients C_{b} in their turn can be determined based on the codewords of the received signal. If denote R={R}—the coefficients of the received polynomial message, then, as long as F=P*R; (1) can be re-written as

$${C}_{b} = {P}_{B}^{- 1} * F = {P}_{B}^{- 1} * P * R = TT * R , \qquad ( 3 )$$

where TT—the full K*(n+1) matrix consisting of all K−1 LS T_{I} and the identity matrix. The example of TT for K=4, n=15 is in Appendix.

Every j-th entry of C_{b} in (4) can be calculated as

$$\begin{matrix}K K - 1 \\ {C}_{b} ( j ) = {R}_{j} + \sum ( {a}_{k} * \sum {R}_{m} ) \\ k = 1 m = 1 , m \sim = j\end{matrix} , \qquad ( 4 )$$

where Rₘ—the related to corresponding aₖ codeword in each m-th group when doing vector-matrix multiplication (3), and every row of big matrix TT contains K−1 entries aₖ each and one 1 due to the property 1. So, in order to accomplish (4) its necessary just K² multiplications, adding another K² for doing (2)—totally 2K² multiplications. For comparison the syndromes calculation through the standard Horner' scheme requires nK˜=K³ multiplications.

Algorithm is applicable and efficient for any other cases RS(n, n−K), when n+1=2^{2q}, K=2^{2r}, where r<=q. Then TT matrix consists of (n+1−K)/K/(K−1) kinds (s=1, . . . (n+1−K)/K/K−1) of (K−1) LSₛ of K entries each and a unity matrix, and (n+1−K)/K/(K−1) alphabets A consist of the K different entries each. For example when n=255, K=4 (4*256)-sized TT matrix consists of 21 troikas of LSₛ. Generally

$$\begin{matrix}( n + 1 - K ) / K ( K - 1 ) & K K - 1 \\ {C}_{b} ( j ) = {R}_{j} + \sum & [ \sum ( {a}_{k} * \sum {R}_{m} ) ] \\ s = 1 & k = 1 m = 1 , m \sim = j\end{matrix}$$

It means for vector of length 256 being multiplied by it just K*(n+1)²/3 multiplications are necessary, that corresponds to the three times less multiplications used.

The matrix T can be constructed using the given set J, matrix W, matrix VV (consisting of the first rows of every LS T_{I}) and arrangement array IR (a reordering matrix derived from J and W). The examples of VV matrix are in Appendix as well.

In order to accomplish T inverse it makes sense to use the property 3 and take into consideration the matrix T^{A}—the matrix converted from T through its mirroring around the secondary SouthWest-NorthEast adjunct diagonal, and the matrix U=T^{A}*T. Obviously

$${T}^{- 1} = {U}^{- 1} * {T}^{A}$$

The property 3 means calculating the product U can be done without any arithmetic operation but doing just logical ones and determining the possible overlapping between different columns of T. U is symmetric around the secondary adjunct diagonal (A-symmetric) and that secondary diagonal consists of zeros and there are zero quadrants around it. U breaks up geometrically into four quadrants.

$$\begin{matrix}U = [ \begin{matrix}{B}^{A} & D\end{matrix} ] \\ [ \begin{matrix}A & B ]\end{matrix}\end{matrix}$$

In order to inverse matrix 4*4 sized U is enough to simply swap two of it's A-symmetrical quadrants B, B^{A} and multiply by the scalar constant. For any K-sized U matrix should we break it up into four quadrants, its inverse can be done as follows [6]

$${U}^{- 1} = {U}_{1} * {U}_{2} * {U}_{3} \qquad ( 5 )$$

$$\begin{matrix}{U}_{1} = [ I & 0 ] \\ [ {D}^{- 1} * {B}^{A} & I ]\end{matrix}$$

$$\begin{matrix}{U}_{2} = [ ( A + B * {D}^{- 1} * {B}^{A} & 0 ] \\ [ 0 & {D}^{- 1} ]\end{matrix}$$

$$\begin{matrix}{U}_{3} = [ B * {D}^{- 1} & I ] \\ [ I & 0 ]\end{matrix}$$

where A+B*D⁻¹*B^{A}—so called the Schur component, I—an identity matrix.

So inverse of K-sized U can be reduced to the manipulations with K/2-sized ones. The same valid to those obtained K/2-sized matrices etc, so it's possible to find K/2-sized U⁻¹ recursively. The crucial moment here is all involved matrices of lesser sizes and their Schur components posses the same properties as original U (see above) and formula (5) can be applied to them as well. In order to achieve that after formation of T matrix their columns should be put together into groups. That re-ordering is implemented inside the input C_{b} and result E vector at the end, and both permutations can be described with index arrangement arrays IR and reordering matrices O_{H} and O_{V}.

So the second stage of finding error magnitudes reduces to consecutive vector-matrix multiplications starting with C_{b}.

$$E = {O}_{H} {U}_{1} {U}_{2} {U}_{3} {O}_{V} {T}^{A} {C}_{b} \qquad ( 6 )$$

All the developed algorithms are successfully simulated in MATLAB.

### Operational Details

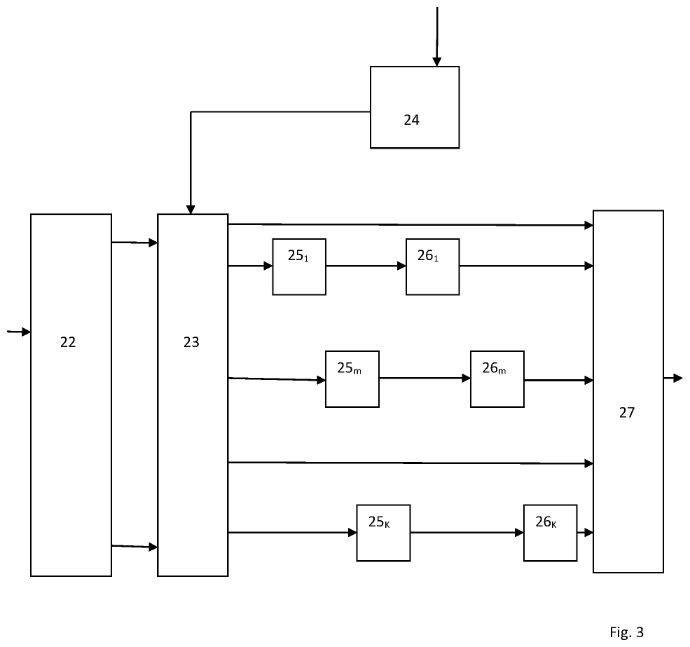

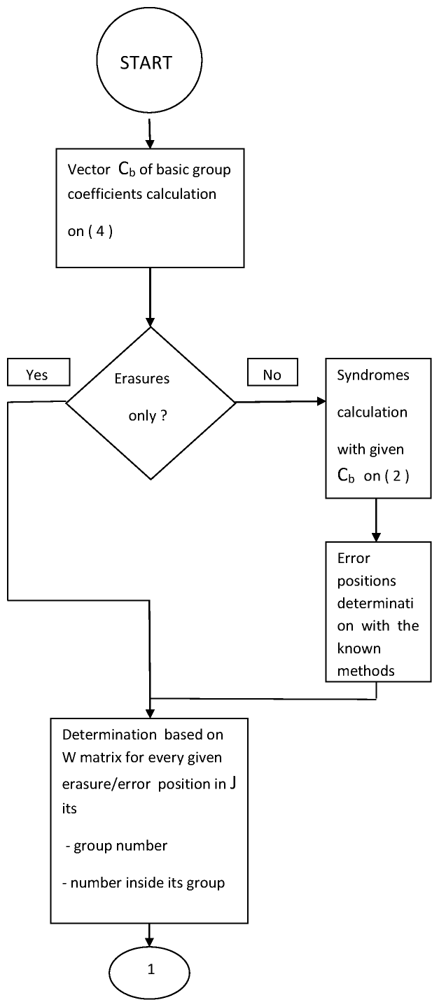

VMM (a vector-matrix multiplier) 7 implements calculations (4) with the RS codewords coming to it, its embodiment is shown on FIG. 3; the result-a vector of basic group coefficients are fed in to the memory 13 for errors magnitudes determination and to the block 12. VMM 12 implements calculations on (2) to determine syndromes magnitudes, the entries of P_{B} matrix are stored in the block.

The given and/or found errors and erasures positions (indexes of the polynomials) j€J are fed the logical scheme 8, which determines for every entry of J its group number and its position in the group, based on the matrix W stored in the special memory 9. The logical scheme 10 re-orders the given indexes from J in order to put together indexes related to the same group and sorts those groups of indexes in descending order according to the number of components in each group, to produce index reordering array IR.

A logical scheme 14 implements re-ordering the basic group coefficients according to the received IR (O_{V}).

A memory 11 stores the matrix VV—the first (basic) rows of every LS T_{I}, and the logical scheme 15 forms the matrix T (and correspondingly T^{A} and U) based on content of 11 and the reordering array IR.

A VMM 16—the “engine” of the structure—consequently implements several vector-matrix multiplication on (6). The block 17 builds the parts of U inverse U₁, U₂, U₃ in accordance to used formula (5). The block 18—a logical scheme for re-ordering entries of the result E vector in accordance to IR (O_{H}).

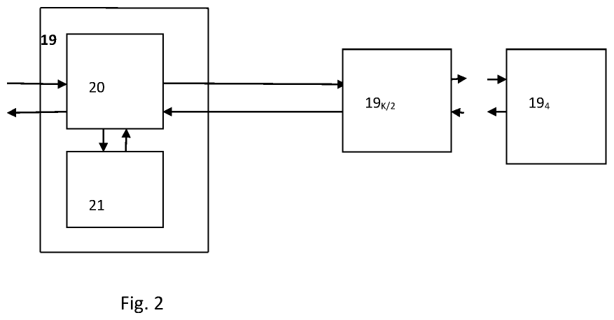

FIG. 2 describes the block 17—the most complicated part of the invention—recursive structure for determination of the co-factors in calculation of U inverse (5). It consists of serially connected blocks 19 for determination of inverses of the derived matrices of sizes R lesser than K (R=K/2, K/4, . . . 4). Each bock 19 consists of two connected blocks 20—a builder of matrix quadrants and 21—a matrix-by-matrix multiplier for determination the Schur components in (5) and their partial products.

A block 20 is a logical scheme for geometrically dividing an input matrix into four quadrants and some other manipulations with them (swapping etc). And every time when it is required to calculate an inverse of a matrix of twice lesser size R (like the obtained quadrants), the block 19 sent it to the another block 19 for processing matrices of two times less size, where the calculations are recursively repeated etc. And in the last block 19 related to K=4 the sub block 21 is omitted because it is not required according to the algorithm.

On the FIG. 3 a logical scheme 24 determines the indexes in the received codeword related to the same entry of the used alphabet in (4) when calculating j-th C_{b} coefficient. It uses the information in the full (n+1)*K conversion matrix TT which can be represented by the matrices J, W and VV stored in the bocks 8, 9, 11.

The symbols in RS codeword related to those determined indexes are passed from the register 22 through the decoder 23 to the corresponding accumulation adders 25. Each adder corresponds to the certain entry in the alphabet A and implements the internal summation in (4).

The multipliers 26 do the actual multiplication of the accumulated sum from the adders 25 outputs by the certain entry of the alphabet A. The last adder 27 implements the external summation in (4).

### Alternative Embodiments

Several embodiments of the invention can be designed reflecting trade-off between hardware requirements versus speed and fastness. There is a broad spectrum of implementation of the flow-chart described on FIGS. 4-6 depending on different levels of computational parallelism and concurrency.

### Appendix

We illustrate our approach for Galois fields of sizes n=15, 255 and 1023. n+1=K²=2^{2q}, q—an integer.

The used primitives polynomials are the following:
for n=15 x⁴+x+1
for n=255 x⁸+x⁴+x³+x²+1
for n=1023 x¹⁰+x³⁺1

The case RS (15,11):

W=[4 2 1 8

0 10 15 5

3 11 14 12

6 9 13 7]

A={9,11,13,14}

The matrix VV:

VV=[1000

13 9 14 11

13 11 9 14

9 11 14 13]

The matrices TT

```
  4 2 1 8 3 11 14 12 6 9 13 7 0 10 15 5
---------------------------------------------------------------------------------------------------------------------------------------
  4I 1 0 0 0 13 11 14 9 13 14 9 11 9 13 14 11
  2I 0 1 0 0 9 14 11 13 11 9 14 13 11 14 13 9
  1I 0 0 1 0 14 9 13 11 9 11 13 14 14 11 9 13
  8I 0 0 0 1 11 13 9 14 14 13 11 9 13 9 11 14
----------------------------------------------------------------------------------------------------------------------------------TT₁
  3I 13 9 14 11 1 0 0 0 13 9 11 14 14 13 11 9
11I 11 14 9 13 0 1 0 0 9 13 14 11 13 14 9 11
14I 14 11 13 9 0 0 1 0 11 14 13 9 11 9 14 13
12I 9 13 11 14 0 0 0 1 14 11 9 13 9 11 13 14
---------------------------------------------------------------------------------------------------------------------------------- TT₂
  6I 13 11 9 14 13 9 11 14 1 0 0 0 11 13 9 14
  9I 14 9 11 13 9 13 14 11 0 1 0 0 13 11 14 9
13I 9 14 13 11 11 14 13 9 0 0 1 0 9 14 11 13
  7I 11 13 14 9 14 11 9 13 0 0 0 1 14 9 13 11
-----------------------------------------------------------------------------------------------------------------------------------TT₃
  0I 9 11 14 13 14 13 11 9 11 13 9 14 1 0 0 0
10I 13 14 11 9 13 14 9 11 13 11 14 9 0 1 0 0
15I 14 13 9 11 11 9 14 13 9 14 11 13 0 1 0 0
  5I 11 9 13 14 9 11 13 14 14 9 13 11 0 0 0 1
----------------------------------------------------------------------------------------------------------- ----------------------- TT₄.
=====================================
```

The case RS (255,239):

The ‘magical” 16*16 matrix W for that case looks like

| | |
|---|---|
| [ | 85 170 255 0 17 68 34 136 51 238 187 204 102 221 153 119 |
| | 1 25 41 157 16 145 146 217 62 90 3 223 227 165 48 253 |
| | 7 112 219 189 111 246 28 193 131 56 222 237 224 14 183 123 |

```
    13 99 208 54 23 196 113 76 92 19 197 49 141 52 216 67
    15 33 79 174 107 58 65 162 244 234 240 18 20 42 182 163
```

9 120 122 117 10 21 209 91 160 81 29 181 144 135 167 87
5 138 173 232 186 61 132 60 168 80 142 218 211 171 195 72
2 50 59 82 37 179 35 32 251 96 199 75 180 124 6 191
4 100 164 118 70 64 103 74 127 12 105 248 192 247 143 150
8 200 236 73 206 148 128 140 45 31 129 239 24 254 210 241

```
    11 245 114 166 207 205 202 94 106 39 95 176 229 172 220 252
    22 235 77 228 149 188 155 159 249 185 203 89 78 212 190 97
    30 66 93 158 130 69 116 214 71 109 40 84 213 233 225 36
    43 121 63 55 154 201 215 44 178 151 243 115 169 156 125 194
    26 198 108 161 226 152 137 46 134 177 27 104 38 184 139 98
    47 101 231 230 133 250 83 57 175 88 147 53 86 242 110 126 ];
A = {88, 14, 27, 168, 39, 101, 222, 97, 37, 144, 184, 45, 58, 84, 151, 192 }
```

The matrix VV for the case is the following:

1 0 0 0 0 0 0 0 0 0 0 0 0 0 0 0 0
27 184 39 58 84 101 45 168 192 97 144 14 88 37 222 151
37 97 27 84 144 222 168 58 39 45 151 14 101 184 192 88
184 192 101 88 144 58 222 168 84 37 27 97 151 45 14 39
144 184 37 45 88 168 14 27 97 39 222 101 151 84 192 58
192 37 168 39 14 222 84 184 151 144 27 101 88 97 58 45
192 144 14 97 101 168 45 84 222 88 37 151 58 184 27 39
58 88 97 45 39 37 192 168 151 27 101 144 222 184 84 14
144 45 184 37 39 222 97 101 192 84 58 151 27 88 14 168
37 14 58 101 168 184 97 151 84 39 144 88 222 192 27 45
151 101 144 27 37 168 192 39 84 222 184 14 45 88 58 97
168 27 14 88 97 222 101 39 45 184 144 37 192 151 84 58
58 14 101 37 88 84 144 39 222 45 192 27 184 97 168 151
151 184 168 97 144 84 39 88 14 101 58 37 222 27 45 192
222 58 168 144 39 151 14 45 84 97 37 27 192 101 184 88
84 168 101 45 37 222 88 151 144 97 14 192 58 27 39 184
=====================================================

The case RS (1023,991): the alphabet set A:

```
A = {468 486 154 236 626 1023 457 69 332 188 996 280 53 213 225 688 59 494 458...
  693 564 11 850 768 745 421 139 681 698 712 207 237 }
The “magical” 32 * 32 matrix W =
[297 66 1023 0 33 660 495 825 396 363 726 792 429 561 165 264...
      957 231 330 528 198 693 990 627 132 594 99 858 462 891 759 924
1 77 266 468 85 434 589 674 177 942 477 549 102 907...
    32 418 195 380 79 618 419 833 58 109 422 920 205 796 339 482 328 654
2 154 643 838 75 954 116 218 936 532 964 678 158 213...
  204 791 656 285 155 325 760 390 64 836 170 868 844 817 410 569 861 354
3 10 1009 1003 383 575 240 490 555 821 229 323 697 369 982 808...
      167 106 78 956 320 96 734 281 378 1001 925 450 843 319 519 335
4 308 780 497 333 905 128 649 653 263 115 820 310 650...
  316 426 699 708 232 436 570 289 408 559 150 885 340 713 665 611 41 849
5 513 789 922 1012 189 478 39 771 679 703 799 404 491 652 367 160...
      48 696 860 1016 1013 245 120 225 974 671 933 626 673 53 595
6 20 192 640 646 458 445 562 983 995 638 663 156 889...
  371 738 15 670 480 980 212 334 941 593 766 127 756 979 827 900 619 87
7 1020 141 744 857 476 1002 284 910 826 904 351 279 420 221 68...
      236 902 130 934 635 270 182 598 456 883 709 722 224 927 220 391
8 616 578 117 617 230 816 95 994 537 199 307 464 872...
  620 277 82 675 256 275 393 375 632 852 666 787 300 747 680 403 526 283
9 324 147 503 1021 152 577 88 959 772 50 770 612 751 795 725 92...
      344 888 694 89 219 466 104 802 870 259 590 138 288 898 778
11 200 356 876 262 352 767 19 368 353 989 588 552 129 1015 608...
      854 111 958 402 411 139 416 841 36 273 483 730 523 43 13 314
12 40 668 424 303 253 859 163 257 384 777 631 960 937...
  312 755 215 174 890 101 317 30 742 453 269 916 509 254 489 935 967 943
14 1017 540 247 702 785 364 173 465 282 831 448 260 845 558 840...
      440 782 981 568 781 472 442 136 691 952 912 743 395 421 629 797
16 209 750 786 614 398 241 681 234 133 806 337 512 550...
  928 721 29 566 609 190 327 164 217 554 211 460 309 551 600 471 51 965
17 311 186 291 988 114 737 59 837 105 433 692 926 579...
  470 119 865 55 255 769 226 855 56 999 544 745 718 739 762 71 661 557
18 648 438 178 517 100 932 208 1006 294 576 276 753 365 201 479...
      773 533 131 176 688 184 567 427 1019 304 581 717 518 157 521 895
21 305 597 913 963 574 379 527 875 496 126 977 823 834...
  392 146 572 690 553 672 61 917 972 914 414 604 700 929 268 580 90 761
22 400 278 822 153 955 832 659 729 712 86 23 893 804 81 258...
      26 628 511 38 222 685 1007 193 524 704 72 546 966 437 706 736
24 80 60 634 239 531 461 906 848 313 847 978 757 202 897 851...
      911 863 695 326 348 430 624 487 606 506 538 809 1018 508 768 514
25 385 909 874 389 449 76 1022 401 435 444 347 386 991 306...
      887 46 172 233 52 641 295 144 69 763 585 44 800 162 516 621 556
27 206 662 505 830 814 601 498 864 454 475 573 481 428 945 878...
      280 169 591 818 47 397 293 776 724 815 873 735 473 985 315 1014
28 1011 944 539 896 639 884 272 494 57 842 790 939 113 520 667...
      235 571 728 346 541 880 93 657 381 547 359 881 801 463 564 930
31 758 499 180 137 536 803 171 921 805 931 252 727 992...
  377 835 122 811 610 42 185 828 903 125 784 292 121 357 623 645 321 83
34 622 687 452 361 866 112 975 582 372 142 501 510 515...
  829 135 299 91 451 118 110 707 940 238 953 228 65 467 413 455 210 651
35 149 387 793 894 423 188 565 711 443 869 871 997 602...
  850 191 676 97 824 108 187 251 246 877 901 689 237 987 318 203 969 358
37 161 882 603 74 322 265 296 853 698 592 530 148 644...
  746 343 813 441 459 366 341 682 683 373 918 732 349 938 741 183 686 469
45 892 976 350 1000 63 923 417 664 522 486 457 810 968 287 993...
701 775 788 336 73 196 970 542 949 248 345 286 207 302 290 134
49 274 998 360 84 197 642 166 370 633 587 819 839 504...
  584 545 783 250 754 647 242 714 583 342 493 62 961 431 599 244 267 223
54 412 794 94 123 950 586 529 1010 301 947 946 159 613 962 856...
      630 1005 179 996 338 560 867 733 637 605 425 607 723 447 908 705
67 145 684 143 243 740 484 405 534 446 271 485 175 488 500 543...
      720 973 168 394 655 1008 548 98 261 332 862 899 124 986 615 151
70 298 502 374 719 715 492 731 563 774 406 636 625 216...
  971 181 915 716 376 107 194 329 677 382 765 846 779 355 474 951 886 399
103 525 432 227 919 362 409 807 669 507 415 407 439 984 388 658...
      535 710 214 752 331 764 249 812 879 948 1004 748 749 798 596 140
]
```

What is claimed is:

1. A method of syndrome, error and erasure magnitudes calculation when performing Reed-Solomon decoding (n=2^{2q}−1, n−K), (K=2^{2r}, r<=q) implemented through preliminary calculating coefficients of syndromes expansion into the series of polynomials with their powers belonging to a pre-determined basic group of K powers,
when all n available powers of used polynomials break up into (n+1)/K groups with K powers each in accordance to a discovered table of their breaking up, enabling a situation when matrices for conversion of the coefficients of syndromes expansion in the series of K polynomials of the powers belonging to a certain group of said table into the coefficients of syndromes expansion in the series of K polynomials of the powers belonging to an another group of said table are the Latin Squares with their entries belonging to (n+1−K)/K/(K−1) fixed K-limited alphabets aₖ^{s} (k=1, . . . K; s=1, . . . (n+1—K)/K/(K−1)) of elements of GF (n),
comprising of calculating a vector C_{b}=c_{b}(j) of the basic group coefficients of syndrome expansion, consisting of
(a) choosing a set of K powers of polynomials as a basic group in said table,
(b) for every S=1, . . . (n+1−K)/K/(K−1)
calculating for each entry of said vector (K−1) sums of K received codewords Rₘ according to the corresponding row of the corresponding conversion matrix,
multiplying each sum by the corresponding entry aₖ^{s} of said alphabets, producing (K−1) products,
summing up those products,
(c) repeating (b) for all S,
(d) the final summing up the related codeword, overall implementing
$$\begin{matrix}( n + 1 - K ) / K ( K - 1 ) & K K - 1 \\ {C}_{b} ( j ) = {R}_{j} + \sum & [ \sum ( {a}_{k} * \sum {R}_{m} ) ] \\ s = 1 & k = 1 m = 1 , m \sim = j\end{matrix} .$$

2. The method of syndrome magnitude calculation of claim 1 consisting of multiplying said vector of coefficients C_{b} by a predetermined K*K matrix of the basic group polynomials P_{B} to produce syndromes vector F
$$F = {P}_{B} * {C}_{b}$$

3. The method of error and erasure (with the given positions−power numbers J) magnitudes calculation of claim 1 comprising multiplying said vector C_{b} by inverse of a matrix T of conversion of the coefficients of syndromes expansion in the series of K polynomials of the powers belonging to the set of said given power numbers J into the coefficients of syndromes expansion in the series of K polynomials of the powers belonging to the basic group yielding a vector of said magnitudes E
$$E = {T}^{- 1} * {C}_{b} ,$$
where said matrix T is constructed with columns of said conversion matrices and its inverse calculated as a matrix product T⁻¹=U⁻¹ T^{A},
where U=T^{A} T—an auxiliary matrix,
T^{A}—the transposed matrix T around its adjunct north-fast-south-west diagonal.

4. The method of error and erasure magnitudes calculation of claim 3, where said inverse of auxiliary matrix U⁻¹ is calculated in accordance with the Schur block decomposition
$${U}^{- 1} = G {O}_{H} {U}_{1} {U}_{2} {U}_{3} {O}_{V} ,$$
where O_{H}, O_{V}—reordering matrices,
G—a diagonal matrix of constants,
$$[ {B}^{A} D ] \qquad \begin{matrix}[ I & 0 ]\end{matrix} \qquad \begin{matrix}[ ( A + B * {D}^{- 1} * {B}^{A} & 0 ]\end{matrix} \qquad \begin{matrix}[ B * {D}^{- 1} & I ]\end{matrix}$$
$$\begin{matrix}U = \\ [ \begin{matrix}A & B ]\end{matrix}\end{matrix} ; \begin{matrix}{U}_{1} = & \\ [ {D}^{- 1} * {B}^{A} & I ]\end{matrix} ; \begin{matrix}{U}_{2} = & \\ [ 0 & {D}^{- 1} ]\end{matrix} ; \begin{matrix}{U}_{3} = & \\ [ I & 0 ]\end{matrix}$$
A, B, B^{A}, D—four quarters of U, K/2-by-K/2 size.
A+B*D⁻¹*B^{A}—the Schur matrix component and D are symmetric matrices with zeros around the secondary diagonal,
I—an identity matrix,
and all the inverses of said matrices of lesser size K=K/2 . . . 8 being calculated in the same manner recursively, for K=4 the inverse of said matrix being the matrix itself with switched two quadrants around its secondary diagonal multiplying by a diagonal matrix of constants.

5. A circuitry for syndrome, error and erasure magnitude calculation when performing Reed-Solomon decoding (n=2^{2q}−1, n−K), (K=22a) comprising
a means for calculation of syndromes expansion coefficients in the series of the polynomials of the basic group,
a logical scheme for determining for every index in the given set of error and erasure positions J its group number and its position number in the group's row of the pre-determined matrix W for breaking up n indexes into K groups with (n+1)/K ones in each,
a memory for storing the matrix W,
a logical scheme for re-ordering indexes from J to produce index array IR, which determines the re-ordering matrices O,
a memory for storing the matrix VV containing the first rows of the conversion matrices,
a means for calculating syndrome magnitudes in accordance to (2),
a buffer memory for the coefficients of the basic group and temporary ones while doing several multiplications (6),
a logical scheme for re-ordering those coefficients in accordance to the IR,
a logical scheme for forming T matrix,
a means (vector-matrix multiplier) for implementing (6),
a means for building U₁, U₂, U₃ matrices up in accordance to (5),
a logical scheme for final re-ordering of coefficients in accordance to the IR.

6. The circuitry of said means for calculation of syndromes expansion coefficients in the series of the polynomials of the basic group of claim 5 comprising
a register to store a received codeword consisting of n symbols,
a logical scheme decoder circuit with n inputs and K outputs for selecting the codewords of the necessary powers in the received message for every alphabet element aₖ,
a logical scheme to control that decoder,
a plurality of K accumulation adders,
a plurality of K multipliers for multiplication by a constant aₖ,
an adder with K+1 inputs,
implementing (4).

7. The means for building up U₁, U₂, U₃ matrices of claim 5 comprising
log₂K−1 means for building up U₁, U₂, U₃ matrices of the lesser sizes K/2, K/4 . . . 8 comprising
a means for selecting the matrix quadrants A, B, C, D according to (5),
a means for matrix-by-matrix multiplication implementing the inverse calculation on (5), and a means for building up U₁, U₂, U₃ matrices for K=4,
comprising a means for selecting the matrix quadrants A, B, C, D.
